(19) United States
(12) Patent Application Publication
(10) Pub. No.: US 2016/0053365 A1
(43) Pub. Date: Feb. 25, 2016

(54) ENCAPSULATED COMPOSITE BACKING PLATE

(71) Applicant: Honeywell International Inc., Morristown, NJ (US)

(72) Inventors: Jaeyeon Kim, Liberty Lake, WA (US); Kevin B. Albaugh, Liberty Lake, WA (US)

(21) Appl. No.: 14/820,336

(22) Filed: Aug. 6, 2015

Related U.S. Application Data
(60) Provisional application No. 62/039,694, filed on Aug. 20, 2014.

(51) Int. Cl. C23C 14/34; B23K 20/02

(52) U.S. Cl. CPC C23C 14/3414; C23C 14/3407; B23K 20/023

(57) ABSTRACT

A backing plate for use with a sputtering target is disclosed including a core component formed of a composite material and an outer layer formed of a metal or metal alloy, wherein the outer layer completely surrounds and covers said core component. A method for recycling such a backing plate is also disclosed.

### CROSS REFERENCE TO RELATED APPLICATION

This application claims the benefit under Title 35, U.S.C. §119(e) of U.S. Provisional Patent Application Ser. No. 62/039,694, entitled “ENCAPSULATED COMPOSITE BACKING PLATE,” filed Aug. 20, 2014, the entire disclosure of which is expressly incorporated herein by reference.

### TECHNICAL FIELD

The present disclosure relates to backing plates for use in physical vapor deposition. The disclosure also relates to methods for recycling backing plates with a spent sputtering target.

### BACKGROUND

Physical vapor deposition (“PVD”) is a process that can be used to deposit a thin film or layer of material onto a wafer, chip, or other surface. A PVD process may be used in semiconductor fabrication processes. In an exemplary PVD process, a sputtering target is bombarded with an energy source such as plasma, one or more lasers, or one or more ion beams, until the atoms from the sputtering target are released into the surrounding atmosphere. The released atoms travel towards the surface of the substrate and coat the surface forming a thin film or layer of material.

A metal or metal alloy target for use in a PVD process can be bonded to a backing plate. In certain situations, current traditional backing plates are made of metals or metal alloys and vary in their ability to meet the required mechanical and handling properties. The target can be bound or attached to backing plates by various bonding methods including, for example, epoxy bonding, soldering, and diffusion bonding.

### SUMMARY

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

Herein presented is a backing plate for use with a sputtering target, which can include a core component formed of a composite material and an outer layer of a metal or metal alloy, the outer layer completely surrounding and covering the core component. In some embodiments, the outer layer is selected from the group consisting of aluminum, vanadium, niobium, copper, titanium, tantalum, tungsten, ruthenium, germanium, selenium, zirconium, molybdenum, hafnium, C18200 copper-chromium alloy, C46400 copper-zinc alloy, C18000 copper-nickel-silicon-chromium alloy, 2000-8000 series aluminum, and any combination thereof.

In some further embodiments, the backing plate has a circular shape and a thickness, the outer layer further comprising an annular flange made of the same material as the outer layer, the annular flange extending radially outwardly of the core component around a periphery of the backing plate. In other embodiments, the backing plate has a substantially rectangular or substantially square shape. In still further embodiments, the annular flange has a thickness less than the backing plate thickness. In some embodiments, the annular flange includes at least one opening extending therethrough.

In some further embodiments, the core component is formed of a metal matrix composite (MMC) including a reinforcing material dispersed in a metal matrix (for example, ceramic particulate, whiskers, or fibers dispersed in a MMC). Still in some other embodiments, the metal matrix is selected from the group consisting of aluminum, vanadium, niobium, copper, titanium, tantalum, tungsten, ruthenium, germanium, selenium, zirconium, molybdenum, hafnium, C18200 copper-chromium alloy, C46400 copper-zinc alloy, C18000 copper-nickel-silicon-chromium alloy, 2000-8000 series aluminum, and any combination thereof. In further embodiments, the core component is formed of a ceramic matrix composite (CMC) including ceramic fibers dispersed in a ceramic matrix.

Also disclosed herein is a backing plate for use with a sputtering target, which can include a core component formed of a composite material, the core component having a circular shape with an upper surface, a lower surface, and a side wall and an annular ring formed of a metal or metal alloy, the outer ring attached to the side wall and surrounding the core component. In some embodiments, the backing plate includes a target interface layer on the upper surface of the core component, the target interface layer formed of a metal or metal alloy.

In some embodiments, at least one of the annular ring and the target interface layer are selected form the group consisting of aluminum, vanadium, niobium, copper, titanium, tantalum, tungsten, ruthenium, germanium, selenium, zirconium, molybdenum, hathium, C18200 copper-chromium alloy, C46400 copper-zinc alloy, C18000 copper-nickel-silicon-chromium alloy, 2000-8000 series aluminum, and any combination thereof. In further embodiments the annular ring includes an annular flange extending radially outwardly thereof and disposed around a periphery of the backing plate. In some other embodiments, the annular flange includes at least one opening extending therethrough.

Still in other embodiments, the core component is formed of a metal matrix composite (MMC) including a reinforcing material dispersed in a metal matrix. The metal matrix can be selected from the group consisting of aluminum, vanadium, niobium, copper, titanium, tantalum, tungsten, ruthenium, germanium, selenium, zirconium, molybdenum, hathium, C18200 copper-chromium alloy, C46400 copper-zinc alloy, C18000 copper-nickel-silicon-chromium alloy, 2000-8000 series aluminum, and any combination thereof.

In other embodiments, the core component is formed of a ceramic matrix composite (CMC) including ceramic fibers dispersed in a ceramic matrix.

Additionally disclosed herein is a method for recycling a backing plate for use with a sputtering target, comprising the steps of: removing an at least partially spent sputtering target from the backing plate; and bonding a sputtering target less spent than the removed sputtering target to the backing plate for use in a physical vapor deposition process.

The method can further include the step of correcting surface imperfections in the backing plate by removing material from an outer surface of the backing plate. In other embodiments, the method further comprises the step of correcting surface imperfections in the backing plate by adding material to an outer surface of the backing plate. Still in other embodiments, the less spent sputtering target is formed of the same material as the removed sputtering target, and the material added to the surface of the backing plate is substantially the same composition of material of the backing plate's original composition.

### BRIEF DESCRIPTION OF THE DRAWINGS

FIG. 1 is a graphical representation of an exemplary PVD device.

FIG. 2 is a top plan view on an exemplary backing plate and sputtering target of the present application.

FIG. 3 is a cross-sectional view of the exemplary backing plate and sputtering target of FIG. 2.

FIG. 4 is a cross-sectional view of another exemplary embodiment of the exemplary backing plate and sputtering target of FIG. 2.

FIGS. 5A-5D are cross-sectional views representing steps of an exemplary recycling process for backing plates of the present disclosure.

### DETAILED DESCRIPTION

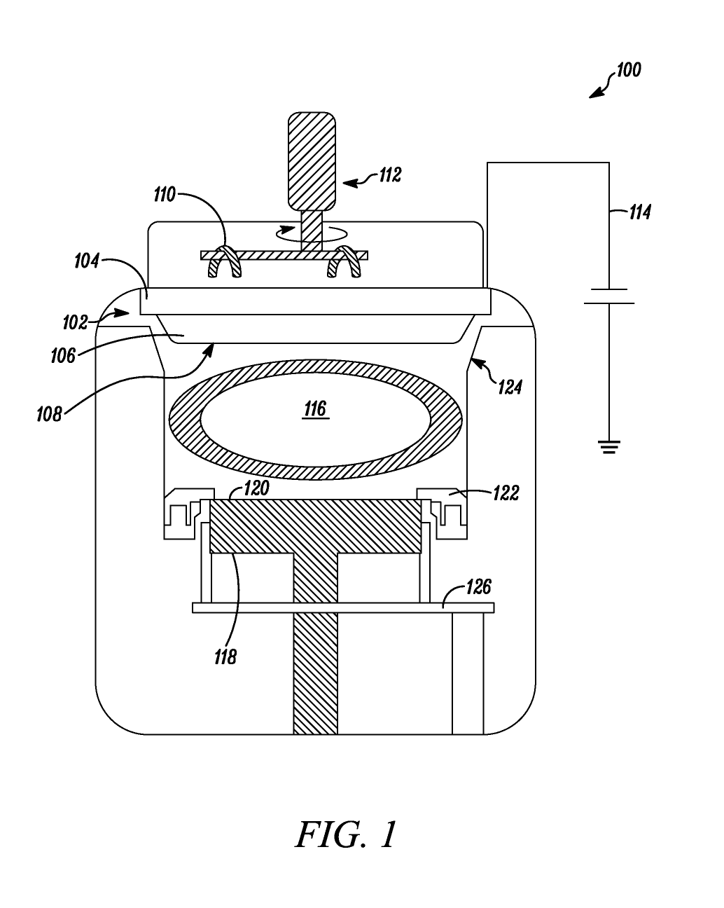

FIG. 1 is a graphical representation of an exemplary direct current (“DC”) PVD device 100. PVD device 100 includes sputtering target assembly 102 (which includes backing plate 104 attached to sputtering target 106 having sputtering surface 108), magnet 110, motor 112, DC power source 114, plasma source 116, platform 118, substrate 120, clamp ring 122, shield 124 and pedestal 126. Sputtering target 106 is disposed above substrate 120 and is positioned such that sputtering surface 108 faces substrate 120. In some embodiments, suitable substrates 120 include wafers used in semiconductor fabrication.

In operation, PVD device 100 causes atoms from sputtering surface 108 to be released and to be deposited on substrate 120. DC power source 114 provides power to the components of PVD device 100. In one embodiment, magnet 110 and motor 112 configure sputtering target 106 to function as a cathode for ion transfer during a PVD process. Platform 118 and pedestal 126 contribute to holding substrate 120 and can allow for placement of substrate 120 at varying heights within PVD device 100. Shield 124 helps prevent the sputtering of atoms outside of a volume defined by shield 124, substrate 120, and sputtering surface 108. Clamp ring 122 allows substrate 120 to be held steady and in place during a PVD process in PVD device 100.

In an exemplary PVD process, sputtering target 106 is bombarded with energy from plasma source 116 until atoms from sputtering surface 108 are released into the surrounding atmosphere and subsequently deposit on substrate 120. In one exemplary use, plasma sputtering is used to deposit a thin metal film onto chips or wafers for use in electronics.

Sputtering target assembly 102 includes sputtering target 106 attached or mounted to backing plate 104. Any configuration of sputtering target assembly 102, including backing plate 104 and sputtering target 106, which allows deposition from sputtering surface 108 to substrate 120 within PVD device 100 is envisioned. For instance, an efficient configuration of sputtering target assembly 102 can include backing plate 104 and sputtering target 106, which allows deposition from sputtering surface 108 to substrate 120 within PVD device 100.

Sputtering target 106 may be formed from any metal suitable for PVD deposition processes. For example, sputtering target 106 may include aluminum, vanadium, niobium, copper, titanium, tantalum, tungsten, ruthenium, germanium, selenium, zirconium, molybdenum, hafnium, and alloys and combinations thereof. When such exemplary metals or alloys are intended to be deposited as a film onto a surface, a metal target is formed from the desired metal or alloy, from which metal atoms will be removed during PVD and deposited onto the surface.

Backing plate 104 may support sputtering target 106 during the PVD deposition process. As discussed herein, a PVD deposition process may cause undesirable physical changes to sputtering target 106, and backing plate 104 may be designed to reduce these undesirable changes. For example, the PVD deposition process may include high heat which would cause sputtering target 106 to warp or deform. The properties of backing plate 104, such as high heat capacity and/or heat conductivity, can help avoid undesirable changes to target 106.

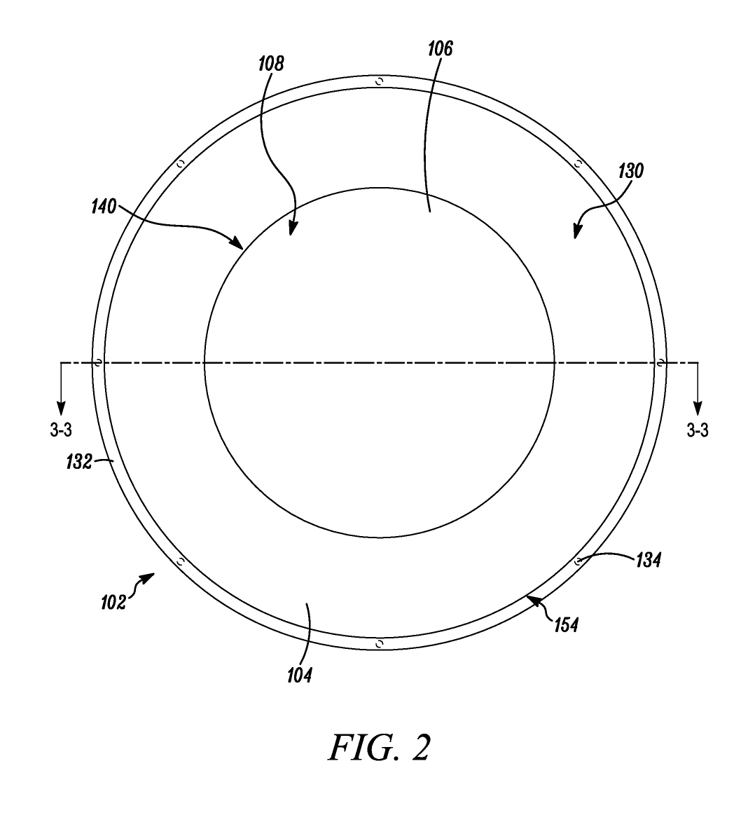

FIG. 2 is a top plan view of sputtering target assembly 102 including backing plate 104 and sputtering target 106. Sputtering surface 108 of sputtering target 106 is shown, along with forward surface 130 of backing plate 104. Sputtering surface 108 and forward surface 130, in some embodiments, are substantially flat or planar. In other embodiments the surfaces may be curved or grooved in any fashion for optimal performance in PVD device 100.

Sputtering target 106 includes outer perimeter 140, which in the exemplary embodiment shown is substantially circular. In other embodiments, outer perimeter 140 could be differently shaped, for example substantially oval-shaped.

FIG. 2 also shows annular flange 132 with openings 134. In the embodiment shown, annular flange 132 extends around the entire outer perimeter of backing plate 104. In other embodiments, annular flange 132 may extend around a portion, but not the entire, perimeter of backing plate 104. Openings 134 may be through-holes formed through annular flange 132. Annular flange 132 and openings 134 may be used to connect or mount sputtering target assembly 102 in PVD device 100. More or fewer openings 134 are envisioned, and any alternative configuration enabling optimum placement in PVD device 100 is also envisioned.

In some embodiments, outer perimeter 154 of backing plate 104 is substantially circular and is larger than outer perimeter 140 of sputtering target 106. In other embodiments, outer perimeter 154 of backing plate 104 may be a shape other than substantially circular and not concentric to outer perimeter 140 of sputtering target 106. For example, outer perimeter 154 may be substantially oval-shaped. In some embodiments, backing plate 104 and sputtering target 106 may have the same or substantially the same cross-sectional shape as defined about their respective outer perimeters 154, 140 and be concentric relative to one another. In other embodiments, backing plate 104 and sputtering target 106 need not have the same or substantially same shape for outer perimeters 154, 140. In some embodiments, backing plate 104 and sputtering target 106 may have substantially differently sized outer perimeters 154, 140 depending on the PVD application.

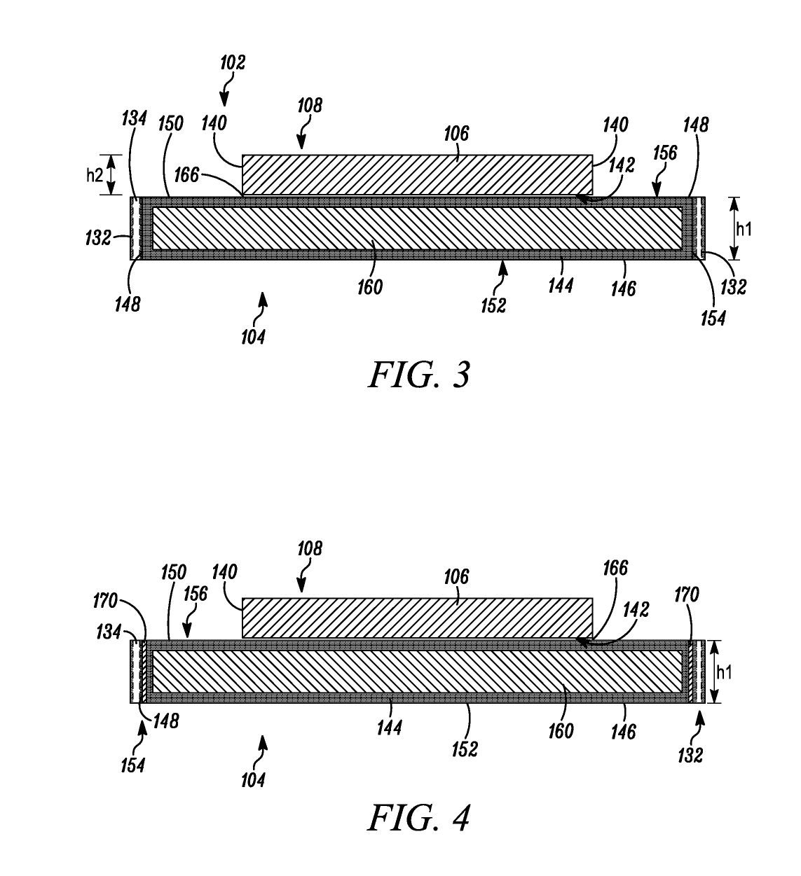

FIG. 3 is a cross-sectional side plan view of sputtering target assembly 102 taken along line 3-3 of FIG. 2. Sputtering target 106 further includes rearward surface 142. Rearward surface 142 may be disposed opposite or substantially opposite to sputtering surface 108. Rearward surface 142 additionally or alternatively may be parallel or substantially parallel to sputtering surface 108, and/or parallel or substantially parallel to a forward surface 156 of backing plate 102 (described further below). In some embodiments, sputtering surface 108 and rearward surface 142 may not be parallel or substantially parallel.

Sputtering surface 108 may be a substantially flat or planar surface. In other embodiments, sputtering surface 108 may have a non-planar configuration, such as a curved or wavy surface, such as a “field enhanced” surface as disclosed in U.S. Pat. No. 8,398,833, assigned to the assignee of the present invention, the disclosure of which is incorporated by reference herein. Similarly, rearward surface 142 may be substantially flat or planar or may be a non-planar configuration. Sputtering surface 108 and rearward surface 142 may have the same or different configurations. For example, each surface may be substantially non-planar surfaces. Alternatively, the surfaces may be different. For example, sputtering surface 108 may be non-planar, and rearward surface 142 may be substantially planar.

Sputtering target 106 may have a height or thickness h2 as defined between sputtering surface 108 and rearward surface 142. Suitable thickness h2 for sputtering target 106 may include thicknesses from about 0.00254 centimeters (about 0.001 inch) to about 254 centimeters (about 100 inches), and may include thicknesses from about 0.254 centimeter (0.1 inch) to about 2.54 centimeters (about 1 inch).

Sputtering target 106 may be formed from any metal suitable for a sputtering target used in a PVD process including, but not limited to, aluminum, vanadium, niobium, copper, titanium, tantalum, tungsten, ruthenium, germanium, selenium, zirconium, molybdenum, hafnium, and alloys and combinations thereof. Other suitable materials for sputtering target 106 can include binary and ternary cobalt, palladium, and iridium; M-RAM (magneto-resistive random access memory)/STT-RAM (spin-transfer torque random access memory) alloys with various compositions including, but not limited to, cobalt-boron-iron, manganese-17-iridium, cobalt-boron, iron-boron, palladium-boron, cobalt-iron-boron, cobalt-platinum, and iridium-manganese. Other suitable materials for sputtering target 106 can include stoichiometric and non-stoichiometric transition metal oxides for Re-RAM (resistive random access memory) materials including titanium oxides, nickel oxide, tantalum oxides, niobium oxides, and tungsten oxides.

Other suitable materials for sputtering target 106 can include solid electrolyte materials for CB-RAM (conductive bridging random access memory) including, but not limited to, a chalcogenide (a chemical compound consisting of at least one chalcogen anion and at least one more electropositive element) such as Ge—Se (germanium-selenium), Ge—S (germanium-sulfur), Oxide based: WO₃. Additionally, chalcogenide alloys for PC-RAM (phase-change random access memory) include materials such as germanium, antimony and tellurium (GST), SbTe (antimony-tellurium), GeTe (germanium-tellurium), GeSe (germanium-selenium), AsSe (arsenic-selenium), and conductor materials like carbon and carbon alloy.

Other suitable materials for sputtering target 106 can include barriers like ruthenium (Ru) and binary ruthenium alloys such as ruthenium-manganese (RuMn), ruthenium-tantalum (RuTa), and ruthenium-titanium (RuTi). Other suitable materials for sputtering target 106 can include salicide materials like NiPt alloys and metal-silicon alloys. Still other suitable materials for sputtering target 106 can include metal gate/High-k (high dielectric constant, a measure of how much charge a material can hold) non-crystalline insulators like La (lanthanum), La₂O₃, Si single-crystal, HfO₂ (hafnium oxide), Al₂O₃, hafnium silicide, borides, carbides, Al₂O₃ and SiO.

In some embodiments, sputtering target 106 has the same or substantially the same material composition throughout. Alternatively, the material composition of target 106 may vary by location. For example, a portion of sputtering target 106 at or near sputtering surface 108 can have one composition while other portions, such as at or near rearward surface 142, have a different composition. For example, rearward surface 142 may include one or more different metals or may contain different ratios of metals than sputtering surface 108.

In some embodiments, sputtering target 106 can be solid or substantially solid. Alternatively, sputtering target 106 may include hollow or substantially hollow portions. Sputtering target 106 can be planar or substantially planar. Alternatively, sputtering target 106 may include convex, concave, and/or hollow portions and may include substantially convex, substantially concave, and substantially hollow portions.

Backing plate 104 has a first side 146, second side 148, and a third side 150 and includes outer layer 144 and inner core 160. Rearward surface 152 is formed along first side 146, outer perimeter 154 is formed along second side 148 and forward surface 156 is formed along forward side 150. In some embodiments, outer layer 144 completely surrounds or encapsulates inner core 160. In other embodiments, outer layer 144 may cover a portion of inner core 160. For example, outer layer 144 may cover all or a portion of first side 146, second side 148, or third side 150 or a combination thereof.

Outer layer 144 including forward surface 156, outer perimeter 154, and rearward surface 152 may include the same metals, alloys, or materials, or they may include different materials from one another. Exemplary materials for forward surface 156, outer perimeter 154, and rearward surface 152 may include, but are not limited to, commercial grade copper, copper/aluminum alloy, molybdenum, titanium, titanium alloys, vanadium, niobium, and alloys of any of the preceding materials. Any suitable metal, alloy, material and/or combination material may form one or more of forward surface 156, outer perimeter 154, and/or rearward surface 152 to form outer layer 144. In some embodiments, outer layer 144 may have the same or substantially the same composition as sputtering target 106. Alternatively, outer layer 144 and sputtering target 106 may have different compositions.

When sputtering target assembly 102 is in use with PVD device 100, rearward surface 152 of backing plate 104 may be in close proximity to magnets 110 and/or in contact or close proximity with water or other cooling means, such as heat sinks and cooling loops.

The thickness of outer layer 144 may be the same or substantially the same along sides 146, 148, 150, or the thickness of outer layer 144 can vary at or along sides 146, 148, 150. For example, first side 146 and third side 150 could be thicker than second side 148. Additionally or alternatively, the thickness may be uniform or non-uniform at or along a side. Suitable thicknesses for sides 146, 148, and 150 of outer layer 144 can vary. In some embodiments, the suitable thickness of outer layer 144 may be sufficient to account for damage caused to the outer layer 144 during a PVD process, such as damage caused by inadvertent sputtering of atoms of the outer layer 144. In some embodiments, outer layer 144 can be as small as about 0.01, 0.05, 0.08, or 0.10 inch (0.03, 0.13, 0.20, or 0.25 centimeter) or as great as about 0.25, 0.50, 0.80, or 1.00 inch (0.64, 1.27, 2.03, or 2.54 centimeters) or any combination thereof.

The height or thickness h1 of backing plate 104 is defined as the distance between forward surface 156 and rearward surface 152. Thickness h1 of backing plate 104 includes the thickness of inner core 160 and the thickness of outer layer 144 (such as outer layer 144 along rearward surface 152 and/or forward surface 156). The thickness h2 of sputtering target 106 and the thickness h1 of backing plate 104 may be the same or different. For example, the thickness h2 of sputtering target 106 may be greater than the thickness h1 of backing plate 104. Alternatively, the thickness h2 of sputtering target 106 may be less than the thickness h1 of the backing plate 104.

In some embodiments, backing plate 104 may be formed from a metal or metal alloy, which is molded, forged, or formed by any other means known in the art to form outer layer 144. In other embodiments, backing plate 104 comprises more than one piece of metal, metal alloy, or any other material, such as epoxy, to mold, forge, or form by any means known in the art outer layer 144. Outer layer 144 can include aluminum, vanadium, niobium, copper, titanium, tantalum, tungsten, ruthenium, germanium, selenium, zirconium, molybdenum, hafnium, or alloys or combinations thereof. For example, outer layer 144 can include hafnium alloys, C18200 copper-chromium alloy, C46400 copper-zinc alloy, C18000 copper-nickel-silicon-chromium alloy, 2000-8000 series aluminum, copper C10100-C15999, high copper alloys C16000-C19999, brass such as C20000-C49999 brass, bronze such as C50000-C69999 bronze, copper nickel alloys such as C70000-C73499 copper nickel, or nickel silver alloys such as C73500-C79999 nickel silver. Other suitable materials for outer layer 144 include iron including ductile irons and cast irons, carbon and/or alloy steels, cast steel, maraging steel, stainless steel, lead and lead alloys, Babbit alloys and solder alloys, magnesium and magnesium alloys, nickel and nickel alloys, refractory alloys, cobalt and cobalt alloys, precipitation hardening stainless steel, iron-based super-alloys, tool steels, and zinc and zinc alloys, and any combination thereof.

Forward surface 156 and rearward surface 152 of backing plate 104 may be disposed substantially oppositely. In some embodiments, forward surface 156 and rearward surface 152 of backing plate 104 are substantially planar. In other embodiments, forward surface 156 and/or rearward surface 152 may be non-planar. For example, forward surface 156 and/or rearward surface 152 may be curved or wavy.

In some embodiments, forward surface 156 and rearward surface 152 of backing plate 104 may be substantially parallel relative to one another. In other embodiments, forward surface 156 and rearward surface 152 may be non-parallel.

Inner core 160 is encapsulated within outer layer 144. Increasing or decreasing the respective thicknesses of outer layer 144 along sides 146, 148, and 150 may increase or decrease the volume of inner core 160. Additionally, adjusting thickness h1 and outer perimeter 154 can be used to adjust the volume of inner core 160.

Inner core 160 includes a composite material. A composite material is a material formed from two or more constituent materials with different physical and/or chemical properties, that when combined, produce a material with characteristics different from the individual components. In some embodiments, composite material can be a metal matrix composite (“MMC”) material. A MMC is a composite material containing a metal matrix and one or more reinforcing materials. MMC's are made by dispersing a reinforcing material into the metal matrix. Certain MMC's are described in Chapter 4 of U.S. Congress, Office of Technology Assessment, Advanced Materials by Design, OTA-E-351 (Washington, D.C.: U.S. Government Printing Office, June 1988) and Kainer, K. U., Metal Matrix Composites. Custom-made Materials for Automotive and Aerospace Engineering., 2006.

The matrix material, or the primary phase, may be monolithic material into which the reinforcement is embedded. In some embodiments, the metal matrix is continuous, completely surrounding the embedded reinforcement material. Suitable metals for metal matrixes include, but are not limited to, aluminum, vanadium, niobium, copper, titanium, tantalum, tungsten, ruthenium, germanium, selenium, zirconium, molybdenum, hafnium, and alloys and combinations thereof. For example, suitable materials for the metal matrix material may include C18200 copper-chromium alloy, C46400 copper-zinc alloy, C18000 copper-nickel-silicon-chromium alloy, 2000-8000 series aluminum, copper C10100-C15999, high copper alloys C16000-C19999, brasses C20000-C49999, bronzes C50000-C69999, copper nickels C70000-C73499, nickel silvers C73500-C79999, or combinations thereof. The MMC of inner core 160 may include any suitable type and amount of metal or metals in the metal matrix.

The metal matrix provides the bulk form of the part or product made of the composite material. For example, the metal matrix may hold the reinforcing material in place. In some embodiments, the metal matrix may enclose and/or conceal the reinforcing material. In some embodiments, when a load is applied to the MMC material, the metal matrix shares the load with the reinforcing material. For example, the metal matrix may deform and the stress may be primarily or substantially born by the reinforcing material.

One or more reinforcement materials can be embedded into the matrix. As described herein, the reinforcement material reinforces the metal matrix. The reinforcement materials may be in the form of fibers, particles, flakes, or otherwise shaped materials. For example, suitable reinforcement materials can be in the form of monofilaments (thin wires), whiskers (short fibers), and/or particles or particulates. In some embodiments, the reinforcing material may provide discontinuous reinforcement. Whiskers and particulate reinforcements are examples of discontinuous reinforcement. In other embodiments, the reinforcing material may provide continuous reinforcement. Monofilament and fiber reinforcement are examples of continuous reinforcement.

If particles are used as the reinforcement material, the particles can be oriented randomly, or the particles may have a preferred or specified orientation. Suitable reinforcing materials for metal matrixes include particles of ceramic (commonly called cermets) and fibers of various materials, including other metals, ceramics, carbon, and boron. The volume fraction of the reinforcement phase can be in the range of between about 0.1% to about 99%, and can also be in the range of about 10% and about 70%.

The reinforcing material additionally or alternatively may include fibers. The MMC of inner core 160 may include any suitable type, orientation and/or amount of fibers. In some embodiments, the fibers may have a random orientation. In other embodiments, the fibers may have an ordered or specified orientation. In some embodiments, continuous MMC's utilize fibers from ceramics, graphite, carbides, and/or oxides as reinforcement components within backing plate 104. In some embodiments, short-fiber reinforced composites include short fibers as the reinforcing material in which the length of the short fibers is less than 100 times the fiber diameter.

In some embodiments, the MMC may include several layers with each layer having a different fiber orientation different than one or more of the adjacent layers. Such laminates may be referred to as laminate composites, multilayer composites or angle-ply composites.

In other uses of MMC's, carbon nanotube reinforced metal matrix (“MM-CNT”) composites can be prepared through a variety of processing techniques and can provide a variety of advantageous properties. Such processing techniques and properties are described in Bakshi, S. R., et al., Carbon nanotube reinforced metal matrix composites—a review, International Materials Reviews 2010, vol. 55, no. 1, pp. 41-64.

The reinforcement of metals by way of a metal matrix composite may increase yield strength and tensile strength at room temperature and above while maintaining a minimum ductility or toughness; increase creep resistance at higher temperatures compared to that of conventional alloys; increase fatigue strength, particularly at higher temperatures; improve thermal shock resistance; improve corrosion resistance; increase Young's modulus; and/or reduce thermal elongation.

The reinforcing material may be selected to serve a structural task (e.g., reinforcing the compound). Additionally or alternatively, the reinforcing material may be selected to change one or more physical properties such as wear resistance, friction coefficient, and thermal conductivity.

Certain examples of MMC systems follow. An aluminum matrix may be used in conjunction with continuous fibers, such as boron, silicon carbide, alumina, and/or graphite fibers. The aluminum matrix may also be used with discontinuous fibers such as alumina, and/or alumina-silica fibers. Silicon carbide “whiskers” could be used with the aluminum matrix. Furthermore, particulates such as silicon carbide and/or boron carbide could be used in the matrix.

A magnesium matrix may be used in conjunction with continuous fibers, such as graphite and/or alumina. Furthermore, silicon carbide whiskers could be used, and/or particulates such as silicon carbide and/or boron carbide.

A titanium matrix may be used in conjunction with continuous fibers such as silicon carbide and/or coated boron. Particulates, such as titanium carbide, could also be used in conjunction with a titanium matrix.

A copper matrix may be used in conjunction with continuous fibers such as graphite and/or silicon carbide. Wires made from materials such as niobium-titanium, and/or niobium-tin can be used in conjunction with a copper matrix. Particulates such as silicon carbide, boron carbide, and/or titanium carbide can also be used with a copper matrix.

A superalloy matrix may include wires imbedded in the matrix. In one example, the wires may be made from tungsten.

Continuous reinforcement can use monofilament wires or fibers such as carbon fibers or silicon carbide. In some embodiments, the fibers are embedded into the matrix in a certain or specified direction and the result is an anisotropic structure in which the alignment of the material affects its strength. Any ordering of reinforcement materials within composite material is envisioned so as to impart beneficial properties to backing plate 104 (see, for example, FIGS. 3-4).

In some instances, the properties of MMC's may provide advantages over the properties of monolithic metal backing plates, specifically with regard to modulus, temperature resistance, strength, hardness, conductivity, dimensional dampening, and/or weight. For example, MMC's may have a more desirable elastic modulus than a metal backing plate. Elastic modulus, or modulus of elasticity, measures an object or substance's resistance to being deformed elastically (i.e., non-permanently) when a force is applied to it. In some embodiments, increasing the elastic modulus of backing plate 104 (such as by the incorporation of inner core 160), allows backing plate 104 to resist elastic deformation during a PVD process.

Temperature resistance refers to the ability of a material to resist an increase or decrease in temperature when a heat source is applied or removed. Composite material may be used to increase the temperature resistance of backing plate 104 so that its temperature is relatively stable during a PVD process. MMC's may offer improved elevated-temperature strength and modulus over metals. For example, the reinforcing material may make it possible to extend the useful temperature range of low density metals such as aluminum, which have limited high temperature capability for PVD applications. In some embodiments MMC's may have higher strength and stiffness than other available backing plate materials. This characteristic could help prevent warping or bending of backing plate 104 and/or target 106 during a high heat PVD process.

Alternatively or additionally, composite material may increase the heat conductivity of backing plate 104. In some embodiments, MMC's may be good heat conductors. For example, when using high thermal conductivity graphite fibers, aluminum-matrix or copper-matrix, MMC's can have very high thermal conductivity, compared with other types of composites. For example, during a PVD process in PVD device 100, backing plate 104 may allow heat built up in target 106 to be dispersed throughout backing plate 104 by increased heat conductivity of inner core 160. In some embodiments, backing plate 104 may be used in a PVD process without cooling channels, cooling loops, heat sinks, and/or similar secondary cooling means in the backing plate.

Strength refers to a material's ability to resist stresses and strains. Composite material may increase the strength of backing plate 104, such that during a PVD process in PVD device 100, backing plate 104 has an increased resistance to stresses and strains caused during the process. Related to strength, MMC's may have a better wear resistance as compared to that of monolithic metals. For example, inclusion of hard ceramic reinforcing material in the MMC may provide an improved wear resistance. Such advantageous wear resistance could be imparted to backing plate 104 by using an advantageous composite material.

Hardness is a measure of how resistant solid matter is to various kinds of permanent shape change when a force is applied. Composite material may be selected to increase or decrease the hardness of backing plate 104, making backing plate 104 more or less resistant to various kinds of permanent shape change when a force is applied.

Electrical conductivity is a measure of a material's ability to conduct an electric current. Composite material may increase or decrease the electrical conductivity of backing plate 104 to make backing plate 104 more or less resistant to electrical conduction during a PVD process in PVD device 100.

Dimensional dampening refers to damping ratio, a dimensionless measure describing how oscillations in a system decay after a disturbance. Composite material may increase or decrease the dimensional dampening of backing plate 104 to make backing plate 104 more or less resistant to oscillation in PVD device 100 during a PVD process.

In some embodiments, the MMC may be selected to reduce the coefficient of thermal expansion. For example, the introduction of silicon carbide particulate into a metal matrix, such as an aluminum metal matrix, results in a MMC having lower coefficients of thermal expansion. By choosing an appropriate composition, the coefficient of thermal expansion can be near zero in some MMC's. Therefore, thermal expansion of backing plate 104 during a PVD process could be reduced or eliminated when composite material reduces the coefficient of thermal expansion.

Any variation in the type, size, shape, amount, arrangement, alloy and/or process for encapsulation is envisioned for inner core 160 containing composite material to provide advantageous properties to backing plate 104. For example, backing plate 104 with composite material may be stronger and have higher heat resistance than a conventional backing plate without composite materials, and at the same time exhibit easy machinability if outer layer 144 is made of conventional backing plate materials, such as a metal or metal alloy. However, any combination of one or more modifications of the properties of backing plate 104 including, but not limited to, elastic modulus, temperature resistance, hardness, strength, electrical conductivity, thermal expansion, and/or dimensional dampening is envisioned.

Additionally or alternatively, composite material may include a ceramic matrix composite (“CMC”). There are many different types of CMC's. Nomenclature of CMC's in the art typically classifies according to the fiber and matrix materials, such as C/SiC, which would represent a CMC made of carbon fibers and a silicon carbide matrix. The fibers of the CMC may be non-oxide or oxide fibers. Suitable mon-oxide fibers used in CMC's include but are not limited to carbon or silicon carbide. Suitable oxide fibers include but are not limited to oxide fibers of alumina, mullite or silica.

In some embodiments, CMC's overcome problem associated with the conventional technical ceramics such as alumina, silicon carbide, aluminum nitride, silicon nitride or zirconia, which can fracture easily under mechanical or thermo-mechanical loads because of cracks initiated by small defects or scratches. The crack resistance, similar to glasses, was very low. To increase the crack resistance or fracture toughness, particles (so-called monocrystalline whiskers or platelets) were embedded into the matrix. The integration of long multi-strand fibers has increased crack resistance, elongation and thermal shock resistance, and resulted in several new applications.

Carbon (C), special silicon carbide (SiC), alumina (Al2O3) and mullite (Al2O3-SiO2) fibers are most commonly used for CMCs. The matrix materials are usually the same, that is C, SiC, alumina and mullite.

Generally, CMC names include a combination of type of fiber/type of matrix. For example, C/C stands for carbon-fiber-reinforced carbon (carbon/carbon), or C/SiC for carbon-fiber-reinforced silicon carbide. Sometimes the manufacturing process is included, and a C/SiC composite manufactured with the liquid polymer infiltration (LPI) process (see below) is abbreviated as LPI-C/SiC.

The important commercially available CMCs are C/C, C/SiC, SiC/SiC and Al2O3/Al2O3. They differ from conventional ceramics in the following properties

The matrix of the CMC may be a non-oxide or an oxide matrix. Suitable non-oxide matrices include but are not limited to silicon carbide, carbon or mixtures of silicon carbide and silicon. Suitable oxide matrices include but are not limited to alumina, zirconia, mullite and other alumino-silicates. In some embodiments, oxide fibers are combined with oxide matrices and non-oxide fibers with non-oxide matrices. For example, CMC types include C/C (carbon-fiber reinforced carbon), C/SiC (carbon-fiber reinforced silicon carbide), SiC/SiC and Ox/Ox, where Ox represents one of the oxide materials mentioned previously.

FIG. 4 shows backing plate 104 with weld 170 disposed between outer perimeter 154 of backing plate 104 and annular flange 132. In the exemplary embodiment, annular flange 132 can be manufactured from different material than backing plate 104 and welded or connected by any other means known in the art to backing plate 104. Weld 170 can include additional material, such as solder, or can simply be a bond between backing plate 104 and annular flange 132. As noted above, any configuration and type of composite materials can be used to impart advantageous properties to backing plate 104.

The encapsulation of inner core 160, including composite material, can be performed with a diffusion bonding operation, by forging, by hot isostatic pressing, or by any other means known in the art. For example, first side 146 and second side 148 may be a single unit without third side 150 at the beginning of a process to encapsulate inner core 160. A desirable composite material, such as a MMC or CMC composite insert, may be placed within first side 146 and second side 148, and third side 150 (also called a lid) can be added on top of first side 146 and second side 148 to encapsulate inner core 160.

A lid may include a copper or aluminum alloy, for example C18200 (CuCr), C46400 (CuZn), C18000, or 2000-8000 series aluminum. Once the lid is resting on top of second side 148, it can be bonded by diffusion bonding or hot isostatic pressing to second side 148. In some embodiments, multi-stack hot isostatic pressing can be used to add third side 150 to first side 146 and second side 148, and/or can be used to bond target 106 to backing plate 104.

Interface layer 166 (is disposed between rearward surface 142 of sputtering target 106 and forward surface 156 of backing plate 104. In some exemplary embodiments, interface layer 166 between rearward surface 142 and forward surface 156 is a bond formed by at least one additional material between backing plate 104 and sputtering target 106. For example, interface layer 166 may be an epoxy bond such as a silver mesh epoxy placed between backing plate 104 and target 106. Alternatively, interface layer 166 may be a solder bond, for example formed when a nickel target, optionally plated to promote wettability, is joined to backing plate 104 with molten solder that hardens as it cools.

In other exemplary embodiments, interface layer 166 between rearward surface 142 and forward surface 156 represents a bond formed between rearward surface 142 and forward surface 156 without any additional material. For example, in diffusion bonding, a common solid-state processing technique for joining similar or dissimilar metals, interdiffusion of atoms between clean metallic surfaces, in contact at an elevated temperature, leads to bonding. Suitable bonding processes include diffusion bonding, hot isostatic pressing (“HIP”), vacuum hot pressing (“VHP”), application of one or more epoxies, and/or hot forging between sputtering target 106 and backing plate 104. In some embodiments, the bond is of suitable strength to withstand a PVD process. Interface layer 166 can be inspected for bond strength by any suitable means known in the art, such as x-ray scan or C-scan.

In the exemplary embodiment of FIG. 3, backing plate 104 includes an optional annular flange 132. In some embodiments, annular flange 132 may axially encompass the entirety of outer perimeter 154, and in other embodiments annular flange 132 may not encompass the entirety of outer perimeter 154. In the embodiment of FIG. 3, flange 132 is part of outer layer 144 and formed of the same material and composition Annular flange 132 optionally can include one or more openings 134 located within annular flange 132, described earlier with regard to FIG. 2. The thickness or height h1 of backing plate 104 and annular flange 132 are shown to be substantially similar in FIG. 3; however, backing plate 104 and annular flange could be different heights or thicknesses suitable for use in PVD device 100.

In the exemplary embodiment of FIG. 4, backing plate 104 includes an optional annular flange 132. In some embodiments, annular flange 132 may axially encompass the entirety of outer perimeter 154, and in other embodiments annular flange 132 may not encompass the entirety of outer perimeter 154. In the embodiment of FIG. 4, flange 132 is an independent ring initially separate from outer layer 144 and welded, forged, or otherwise attached to outer layer 144. Annular flange 132 optionally can include one or more openings 134 located within annular flange 132, described earlier with regard to FIG. 2. The thickness or height h1 of backing plate 104 and annular flange 132 are shown to be substantially similar in FIG. 4; however, backing plate 104 and annular flange could be different heights or thicknesses suitable for use in PVD device 100.

Annular flange 132 may have the same composition, including but not limited to a metal or its alloy, as forward surface 156, outer perimeter 154, and/or rearward surface 152. In some embodiments, annular flange 132 have a different composition than those materials of forward surface 156, outer perimeter 154, and/or rearward surface 152. In some embodiments, a suitable annular flange 132 may be formed of aluminum, vanadium, niobium, copper, titanium, tantalum, tungsten, ruthenium, germanium, selenium, zirconium, molybdenum, hafnium, or alloys of combinations thereof. For example, a suitable annular flange 132 may be formed of C18200 copper-chromium alloy, C46400 copper-zinc alloy, C18000 copper-nickel-silicon-chromium alloy, 2000-8000 series aluminum, copper C10100-C15999, high copper alloys C16000-C19999, brasses C20000-C49999, bronzes C50000-C69999, copper nickels C70000-C73499, nickel silvers C73500-C79999, or any combination thereof.

Annular flange 132 may be formed or molded by any means known in the art. Annular flange 132 can be added to outer perimeter 154 of backing plate 104 by any means known in the art, for example welding, after backing plate 104 is manufactured.

Annular flange 132 optionally can include one or more openings 134 located within annular flange 132. Annular flange 132 with openings 134 can aid in the placement, alignment, positioning, and/or holding of backing plate 104 within PVD device 100 during a PVD process. Openings 134 may allow for secure placement of backing plate 104 and sputtering target 106 into PVD device 100 with bolts, screws, rods, or any similar attachment means known in the art. As shown in FIGS. 2-4, annular flange 132 has the same thickness, h1, as backing plate 104, but in other embodiments annular flange 132 could be of greater or lesser thickness than h1 of backing plate 104.

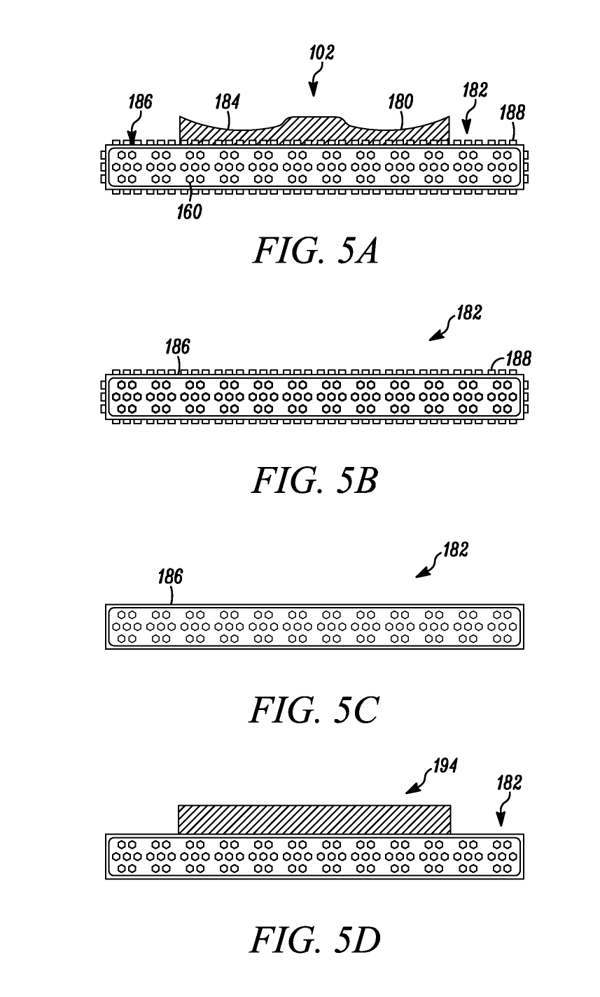

FIGS. 5A-D illustrate an exemplary recycling process for sputtering target assembly 102. FIG. 5A is a cross-sectional view of sputtering target assembly 102 after a sputtering process, which in some embodiments is also the end of the PVD target's life. In some embodiments, sputtering target 180 may be eroded such that sputtering target 180 has a non-planar sputtering surface. Sputtering target 180 may be referred to as a “spent target” after use in a PVD process. For example, sputtering target 180 may have one or more worn grooves 184. Any portion of sputtering target 180 may be spent when a user decides to engage in the recycling process.

Additionally or alternatively, backing plate 182 may contain damage or erosion when the recycling process is engaged. For example, backing plate 182 maybe be damaged or eroded during the PVD process when surface atoms may be inadvertently ejected (or sputtered) from surface 186 of backing plate 182. Such sputtering processes may create eroded portions 188 and/or an uneven surface along surface 186. In the exemplary embodiment shown, surface 186 of backing plate 182 has not been fully eroded or sputtered at any point, and thus during a PVD process in PVD device 100, inner core 160 of backing plate 182, and any materials therein such as composite materials, have been protected and are not exposed.

In the recycling process, sputtering target 180 is removed or separated from backing plate 182, as shown in FIG. 5B. Target 180 and backing plate 182 may be separated by any means known in the art which removes or detaches the bond between sputtering target 180 and backing plate 182. Such removal means include, but are not limited to, milling, grinding, machining, applying heat, and applying one or more chemicals. In some embodiments, 100% or about 100% of sputtering target 180 may be removed or separated from backing plate 182. In other embodiments, a portion of sputtering target 180 may remain attached to backing plate 182 following separation of target 180 and backing plate 182.

After removal of target 180 from backing plate 182, surface 186 of backing plate 182 may be inspected. In some embodiments, if surface 186 of backing plate 182 is determined to be unsatisfactory for future PVD processes, for example either unsatisfactory dimensionally and/or cosmetically, surface 186 may be optionally repaired. For example, surface 186 may be repaired by removing all or a portion of the outer layer. In some embodiments, a portion of the outer layer is removed to the extent required to make surface 186 smooth or planar. For example, a sufficient amount of surface 186 may be removed so as to remove or eliminate eroded portions 188. Surface 186 may be smoothed by any suitable means for removing a portion of surface 186, including but not limited to grinding, milling, machining, and/or polishing.

In some embodiments, in addition to or as an alternative to removing all or a portion of the outer layer, material can be to the outer layer. For example, material such as metal or alloy (the same or different from the original material of surface 186) may be added through forging, welding, molding, soldering, cladding, or any suitable means known in the art, to surface 186. As shown in FIG. 5C, the original character and properties of surface 186 can be restored by additive processes.

After surface 186 of backing plate 182 has been suitably repaired to a smooth state, new target 194 is bonded to backing plate 182 by any means known in the art and previously discussed herein, such as diffusion bonding. Exemplary backing plate recycling processes, such as the embodiment displayed in FIG. 5, are envisioned to be carried out in a continuous process or application. However, a user who uses the target in a PVD application may not be the same user that applies or carries out the recycling process.

According to current manufacturing practices, after PVD processes expend a target, backing plates are discarded and typically are not reused. However, the materials used to manufacture a backing plate with advantageous properties, particularly composite materials, can be expensive, and thus the ability to repair and reuse a backing plate can save the cost and time to manufacture a new backing plate.

Therefore, the instant disclosure presents MMC and/or CMC materials encapsulated with metals, in some instances those metals or alloys used in traditional backing plates, to easily machine such backing plates and allow them to fit into conventional manufacturing processes without machining hard composite materials. In some embodiments, encapsulation of a composite material allows for traditional bonding, such as hot isostatic pressing (“HIP”), vacuum hot pressing (“VHP”), or hot forging between the target and encapsulation material of the backing plate. Encapsulation of a composite material also provides, in some embodiments, a recyclable backing plate available for surface polishing, cleaning, and/or minor repair after use of the attached target.

In one embodiment discussed herein, sputtering target 106 and/or backing plate 104 have a circular outer perimeter. In these embodiments, the diameter of sputtering target 106 is variable, though in one embodiment, sputtering target 106 has a diameter of 32 inches or greater such that sputtering target 106 may be used for sputtering or depositing material onto 450 mm semiconductor wafers. These large diameter sputtering targets, having a diameter of 32 inches or greater, often encounter potential problems associated with warp, deflection, or flexing of the target because of its relatively large diameter. Advantageously, as discussed herein, with the use of backing plate 104 according to the present disclosure which includes an inner core 160 made of a composite material that is mechanically very stiff or rigid, the backing plates 104 disclosed herein may advantageously be used with such sputtering targets 106 which have a diameter of 32 inches or greater for use in sputtering material onto 450 mm semiconductor wafers.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the above described features.

What is claimed is:

1. A backing plate for use with a sputtering target, comprising:
a core component formed of a composite material; and
an outer layer of a metal or metal alloy, said outer layer completely surrounding and covering said core component.

2. The backing plate of claim 1, wherein said outer layer is selected from the group consisting of aluminum, vanadium, niobium, copper, titanium, tantalum, tungsten, ruthenium, germanium, selenium, zirconium, molybdenum, hafnium, and alloys and combinations thereof.

3. The backing plate of claim 1, wherein said backing plate has a circular shape and a thickness, said outer layer further comprising an annular flange made of the same material as said outer layer, said annular flange extending radially outwardly of said core component around a periphery of said backing plate.

4. The backing plate of claim 3, wherein said annular flange has a thickness less than said backing plate thickness.

5. The backing plate of claim 3, wherein said annular flange includes at least one opening extending therethrough.

6. The backing plate of claim 1, wherein said core component is formed of a metal matrix composite (MMC) including a reinforcing material dispersed in a metal matrix.

7. The backing plate of claim 6, wherein the metal matrix is selected from the group consisting of aluminum, vanadium, niobium, copper, titanium, tantalum, tungsten, ruthenium, germanium, selenium, zirconium, molybdenum, hafnium, and alloys and combinations thereof.

8. The backing plate of claim 1, wherein said core component is formed of a ceramic matrix composite (CMC) including ceramic fibers dispersed in a ceramic matrix.

9. A backing plate for use with a sputtering target, comprising:
a core component formed of a composite material, said core component having a circular shape with an upper surface, a lower surface, and a side wall;
an annular ring formed of a metal or metal alloy, said outer ring attached to said side wall and surrounding said core component.

10. The backing plate of claim 9, further comprising a target interface layer on said upper surface of said core component, said target interface layer formed of a metal or metal alloy.

11. The backing plate of claim 10, wherein at least one of said annular ring and said target interface layer are selected from the group consisting of aluminum, vanadium, niobium, copper, titanium, tantalum, tungsten, ruthenium, germanium, selenium, zirconium, molybdenum, hafnium, and alloys and combinations thereof.

12. The backing plate of claim 9, wherein said annular ring includes an annular flange extending radially outwardly thereof and disposed around a periphery of said backing plate.

13. The backing plate of claim 12, wherein said annular flange includes at least one opening extending therethrough.

14. The backing plate of claim 9, wherein said core component is formed of a metal matrix composite (MMC) including a reinforcing material dispersed in a metal matrix.

15. The backing plate of claim 14, wherein the metal matrix is selected from the group consisting of aluminum, vanadium, niobium, copper, titanium, tantalum, tungsten, ruthenium, germanium, selenium, zirconium, molybdenum, hafnium, and alloys and combinations thereof.

16. The backing plate of claim 9, wherein said core component is formed of a ceramic matrix composite (CMC) including ceramic fibers dispersed in a ceramic matrix.

17. A method for recycling a backing plate for use with a sputtering target, comprising the steps of:
removing an at least partially spent sputtering target from the backing plate;
bonding a sputtering target less spent than the removed sputtering target to the backing plate for use in a physical vapor deposition process.

18. The method according to claim 17, further comprising the step of correcting surface imperfections in the backing plate by removing material from an outer surface of the backing plate.

19. The method according to claim 17, further comprising the step of correcting surface imperfections in the backing plate by adding material to an outer surface of the backing plate.

20. The method according to claim 19, wherein the material added to the surface of the backing plate has substantially the same composition as the outer surface of the backing plate.
